(19) United States
(12) Patent Application Publication
(10) Pub. No.: US 2016/0043130 A1
(43) Pub. Date: Feb. 11, 2016

(54) SOLID-STATE IMAGING DEVICE

(71) Applicant: KABUSHIKI KAISHA TOSHIBA, Tokyo (JP)

(72) Inventor: Tatsuya OHGURO, Yokohama Kanagawa (JP)

(73) Assignee: KABUSHIKI KAISHA TOSHIBA, Tokyo (JP)

(21) Appl. No.: 14/558,197

(22) Filed: Dec. 2, 2014

(30) Foreign Application Priority Data
Aug. 8, 2014 (JP) 2014-162841

(51) Int. Cl. H01L 27/146

(52) U.S. Cl. CPC H01L 27/14643; H01L 27/1463; H01L 27/14612; H01L 27/14636; H01L 27/14641

(57) ABSTRACT

According to one embodiment, a solid-state imaging device includes an element isolation film, a photoelectric conversion element, and a transfer transistor. The element isolation film is embedded in a first trench penetrating a semiconductor substrate from a first main surface to a second main surface. The photoelectric conversion element is embedded in a pixel region isolated by the element isolation film, and includes a P-type region formed on the second main surface side along the first trench and an N-type region formed at a region surrounded by the P-type region. The transfer transistor is formed at the first main surface and configured to transfer a charge of the photoelectric conversion element. A part of the element isolation film on the first main surface side is formed of an active region.

### CROSS-REFERENCE TO RELATED APPLICATIONS

This application is based upon and claims the benefit of priority from Japanese Patent Application No. 2014-162841, filed on Aug. 8, 2014; the entire contents of which are incorporated herein by reference.

### FIELD

Embodiments described herein relate generally to a solid-state imaging device.

### BACKGROUND

As an imaging device, there is known a solid-state imaging device of the CMOS type that is manufactured by a CMOS (Complementary Metal-Oxide-Semiconductor) process. The solid-state imaging device of the CMOS type has merits about low voltage and low power consumption. Accordingly, this imaging device attracts attentions as an imaging device for mobile-phone cameras, digital still cameras, and digital video cameras.

Further, as a solid-state imaging device, in recent years, there is produced a solid-state imaging device of the rear incident type configured to receive incident light from the rear side of the substrate, on which no stacked wiring layers are formed, and to perform photoelectric conversion inside the substrate. The solid-state imaging device of the rear incident type does not interrupt incident light by stacked wiring layers, and so it attains a sufficient light condensation characteristic.

As regards the solid-state imaging device of the rear incident type, there is known an FDTI (Front side Deep Trench Isolation) technique, which includes forming deep trenches between pixels to prevent color mixing from being caused between adjacent pixels, and embedding an insulating film in the trenches. In this case, the substrate is separated by the FDTI into parts corresponding to the respective pixels. Accordingly, at least a contact is required for every pixel to fix the substrate potential. However, conventionally, arrangement of this contact has not been studied.

### BRIEF DESCRIPTION OF THE DRAWINGS

FIG. 1 is a top view showing an example of a layout of a solid-state imaging device according to a first embodiment;

FIGS. 2A and 2B include sectional views schematically showing an example of the solid-state imaging device according to the first embodiment;

FIGS. 3A to 3G include top views schematically showing an example of a sequence of a manufacturing method of the solid-state imaging device according to the first embodiment;

FIGS. 4A to 4G include sectional views schematically showing the example of a sequence of a manufacturing method of the solid-state imaging device according to the first embodiment;

FIGS. 5A to 5G include sectional views schematically showing the example of a sequence of a manufacturing method of the solid-state imaging device according to the first embodiment;

FIGS. 6A and 6B include sectional views schematically showing an example of a solid-state imaging device according to a second embodiment;

FIGS. 7A to 7E include top views schematically showing an example of a sequence of a manufacturing method of a solid-state imaging device, in which an FDTI is entirely formed of a metal film, according to the second embodiment;

FIGS. 8A to 8E include sectional views schematically showing the example of a sequence of a manufacturing method of a solid-state imaging device, in which an FDTI is entirely formed of a metal film, according to the second embodiment;

FIGS. 9A and 9B include views schematically showing an example of a configuration of a solid-state imaging device according to a third embodiment;

FIGS. 10A to 10D include top views schematically showing an example of a sequence of a manufacturing method of the solid-state imaging device according to the third embodiment;

FIGS. 11A to 11D include sectional views schematically showing the example of a sequence of a manufacturing method of the solid-state imaging device according to the third embodiment;

FIGS. 12A to 12C include views schematically showing an example of a configuration of a solid-state imaging device according to a fourth embodiment;

FIGS. 13A to 13D include top views schematically showing an example of a sequence of a manufacturing method of the solid-state imaging device according to the fourth embodiment;

FIGS. 14A to 14D include sectional views schematically showing the example of a sequence of a manufacturing method of the solid-state imaging device according to the fourth embodiment;

FIGS. 15A to 15D include sectional views schematically showing the example of a sequence of a manufacturing method of the solid-state imaging device according to the fourth embodiment;

FIG. 16 is a top view schematically showing an example of a pixel element layout;

FIG. 17 is a sectional view schematically showing an example of a structure of the solid-state imaging device explained in the fourth embodiment;

FIG. 18 is a sectional view schematically showing an example of a solid-state imaging device according to a fifth embodiment; and

FIGS. 19A to 19I include sectional views schematically showing an example of a sequence of a manufacturing method of the solid-state imaging device according to the fifth embodiment.

### DETAILED DESCRIPTION

In general, according to one embodiment, a solid-state imaging device includes an element isolation film, a photoelectric conversion element, and a transfer transistor. The element isolation film is embedded in a first trench penetrating a semiconductor substrate from a first main surface to a second main surface. The photoelectric conversion element is embedded in a pixel region isolated by the element isolation film, and includes a P-type region formed on the second main surface side along the first trench and an N-type region formed at a region surrounded by the P-type region. The transfer transistor is formed at the first main surface and configured to transfer a charge of the photoelectric conversion element. A part of the element isolation film on the first main surface side is formed of an active region.

Exemplary embodiments of a solid-state imaging device will be explained below in detail with reference to the accompanying drawings. The present invention is not limited to the following embodiments. The sectional views of solid-state imaging devices used in the following embodiments are schematic, and so the relationship between the thickness and width of each layer and/or the thickness ratios between respective layers may be different from actual states.

As described above, in the case of a solid-state imaging device of the rear incident type that includes pixels isolated from each other by an FDTI, the substrate is separated into parts corresponding to the respective pixels. If a solid-state imaging device having such a configuration is operated without fixing the substrate potential, kinks are generated in the solid-state imaging device. Accordingly, when the solid-state imaging device is operated, the substrate needs to be connected to the ground potential at each of the pixels. In general, each of the pixels is formed with an electrode (which will be referred to as a substrate contact electrode, hereinafter) to be connected to a contact that sets the substrate at the ground potential (which will be referred to as a substrate contact, hereinafter). In a case where the substrate contact electrode is provided in each of the pixels, it is necessary to reduce the areas of the other elements in the pixel. Consequently, the device performance may be deteriorated.

### First Embodiment

In the first embodiment, an explanation will be given of a solid-state imaging device of the rear incident type that includes pixels isolated from each other by an FDTI, along with a structure arranging a substrate contact electrode in each of the pixels without reducing the areas of the other elements in the pixel.

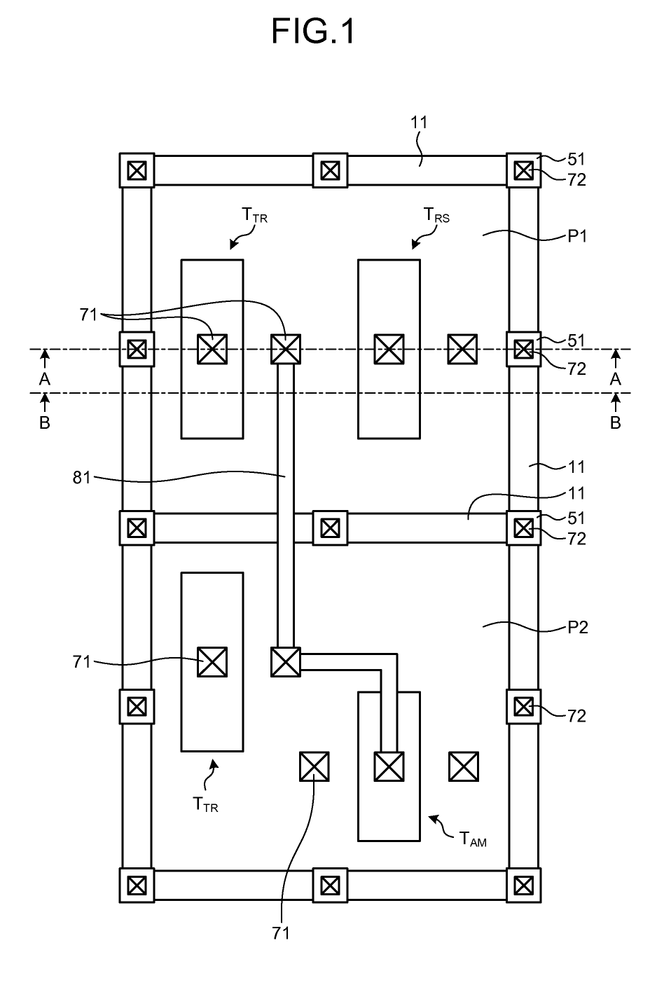

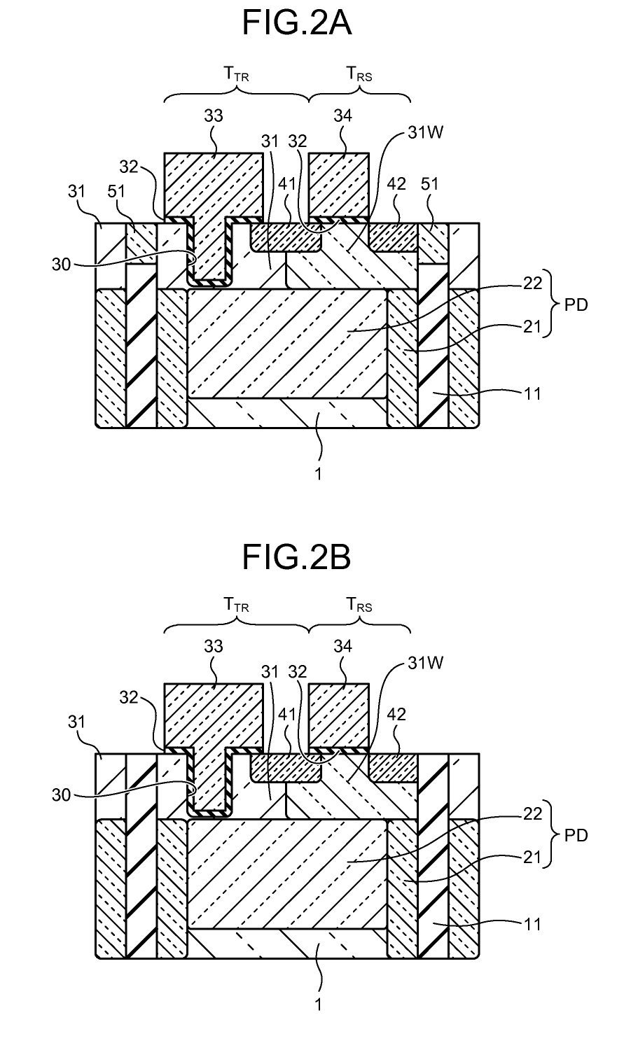

FIG. 1 is a top view showing an example of a layout of a solid-state imaging device according to the first embodiment. FIGS. 2A and 2B include sectional views schematically showing an example of the solid-state imaging device according to the first embodiment, in which FIG. 2A is a sectional view taken along a line A-A in FIG. 1, and FIG. 2B is a sectional view taken along a line B-B in FIG. 1.

The solid-state imaging device has a configuration in which a plurality of pixels are arrayed on a semiconductor substrate 1. Each of the pixels accumulates a charge obtained by photoelectric conversion of light having a predetermined wavelength, and outputs a signal corresponding to the accumulated charge amount to a logic part (not shown). The solid-state imaging device is of the rear incident type, in which a first main surface is equipped with the elements constituting the pixels, and a second main surface (i.e., the rear side of the semiconductor substrate 1) opposite to the first main surface serves as a light incident face. In the example shown in FIG. 2, the light incident face is on the lower side. For example, a P-type silicon substrate may be used as the semiconductor substrate 1. In this specification, the first main surface side and the second main surface side may be respectively referred to as an upper side and a lower side, in terms of directions.

Each of the pixels is electrically isolated from the adjacent pixels by the FDTI 11. In other words, regions surrounded by the FDTI 11 are pixel regions. The FDTI 11 is a DTI formed in the semiconductor substrate 1 from the first main surface side (front side). For example, the depth of the FDTI 11 may be set at 3 μm from the first main surface of the semiconductor substrate 1. The FDTI 11 has a structure including a trench formed in the semiconductor substrate 1 and an element isolation film embedded in the trench. The element isolation film may be formed of a silicon oxide film. Alternately, the element isolation film may be formed of a two-layer structure that includes a silicon oxide film covering the inner wall of the trench and silicon embedded in the trench covered with the silicon oxide film. It suffices for the FDTI 11 if a material having a refractive index different from that of the semiconductor substrate 1 forming the pixels is disposed at the interface with the semiconductor substrate 1. Although not shown in FIG. 2, each of the pixels includes a color filter and a micro-lens arranged on the second main surface side. The color filter limits the wavelength of light to be incident onto the pixel. The micro-lens condenses light to be incident onto the pixel.

In general, each of the pixels includes a photoelectric conversion element PD, a transfer transistor T_{TR}, a floating diffusion portion 41, an amplification transistor T_{AM}, and a reset transistor T_{RS}. The photoelectric conversion element PD is a photodiode that converts incident light to a charge in an amount corresponding to the received light amount, and accumulates the charge. In the example shown in FIG. 2, the photoelectric conversion element PD is composed of a P-type region 21 formed around the FDTI 11 to a predetermined depth from the second main surface side and an N-type region 22 formed at a region surrounded by the P-type region 21 inside the pixel. Accordingly, the PN junction spreads in a direction perpendicular to the substrate surface. The P-type region 21 is formed to a depth of about 2.5 μm from the second main surface side. This is a depth necessary for the photoelectric conversion element PD to maintain the absorption sensitivity to the red component of light, which is less absorbed by the semiconductor substrate 1 (silicon substrate), in a case where different pixels are used to detect respective color components of light having wavelengths corresponding to red, green, and blue. When viewed from the second main surface side, the N-type region 22 is formed from a predetermined depth to the same depth as the P-type region 21.

The transfer transistor T_{TR} is a MISFET (Metal-Insulator-Semiconductor Field Effect Transistor) of the trench type that reads the accumulated charge from the photoelectric conversion element PD and transfers it to the floating diffusion portion 41. The transfer transistor T_{TR} is arranged in a trench 30 formed in a channel region 31 of the first main surface side of the semiconductor substrate 1. The channel region 31 is formed from the first main surface of the semiconductor substrate 1 to a position near the upper side of the photoelectric conversion element PD. The channel region 31 is formed of a low concentration N-type region or low concentration P-type region. The lower end of the trench 30 has a depth that does not reach the photoelectric conversion element PD. The inner wall of the trench 30 is covered with a gate insulating film 32 formed thereon and the trench 30 is filled with a gate electrode 33 formed therein. The gate insulating film 32 may be formed of a silicon oxide film or the like. The gate electrode 33 may be formed of a conductive film, such as a polycrystalline silicon film. In this transfer transistor T_{TR}, the N-type region 22 of the photoelectric conversion element PD serves as a source region and the floating diffusion portion 41 serves as a drain region.

The floating diffusion portion 41 is a region that temporarily holds a charge read by the transfer transistor T_{TR}. The floating diffusion portion 41 is formed of an N-type region. In this example, the floating diffusion portion 41 is formed at a region including the boundary between the channel region 31 and a P-type well 31W described later.

The amplification transistor T_{AM} is a MISFET that amplifies the charge held by the floating diffusion portion 41 and outputs it. Although the sectional structure is not shown in FIG. 2, it has a structure including a gate insulating film and a gate electrode stacked on a channel region on the first main surface side of the semiconductor substrate 1. In the amplification transistor T_{AM}, the source is connected to a signal line (not shown), the drain is connected to a power line (not shown), and the gate electrode is connected to the floating diffusion portion 41. In some cases, a select transistor may be disposed between the amplification transistor T_{AM} and a signal line, or between the amplification transistor T_{AM} and the power line. If the area of the amplification transistor T_{AM} is increased, the random noise is reduced in operation. Accordingly, the area of the amplification transistor T_{AM} is preferably increased as far as possible, if the increase is acceptable within the design range.

The reset transistor T_{RS} is a MISFET that resets (erases) the charge held by the floating diffusion portion 41. The reset transistor T_{RS} uses, as a channel, the P-type well 31W formed on the first main surface side of the semiconductor substrate 1. It has a structure including a gate insulating film 32 and a gate electrode 34 stacked on the P-type well 31W. The reset transistor T_{RS} further includes source/drain regions respectively formed on the opposite sides in the gate length direction. The floating diffusion portion 41 serves as its source region. An N-type region 42 formed near the upper side of the P-type well 31W serves as its drain region.

The example shown in FIGS. 1 and 2 illustrates a structure in which two pixels P1 and P2 share the amplification transistor T_{AM} and the reset transistor T_{RS}. In this case, the shared elements of the two pixels P1 and P2 are connected to each other by contacts 71 and a wiring pattern 81. The photoelectric conversion element PD, the transfer transistor T_{TR}, the amplification transistor T_{AM}, and the reset transistor T_{RS} are elements arranged inside the pixels.

As described above, since the pixels are isolated from each other by FDTI 11 in the solid-state imaging device of the rear incident type, the semiconductor substrate 1 is electrically separated into parts corresponding to the respective pixels. Accordingly, each of the pixels is formed with a substrate contact electrode to be connected to a substrate contact that sets the semiconductor substrate 1 at the ground potential. In the first embodiment, active regions are formed as parts of the FDTI 11 on the first main surface side, and the active regions are respectively used as substrate contact electrodes 51. The substrate contact electrodes 51 are respectively connected to substrate contacts 72. Each of the active regions is formed of a semiconductor film, such as a silicon film doped with a P-type impurity or an N-type impurity.

The substrate contact electrodes 51 are not extended along the entirety of all the sides of the FDTI 11, but are present at points. FIG. 1 shows a case where substrate contact electrodes 51 are provided at three points on each of the sides. In this case, the substrate contact electrodes 51 are used in common for pixels adjacent to each other. The substrate contact electrodes 51 are not present along the entire depth of the FDTI 11, but are present to a predetermined depth from the first main surface. More specifically, the depth of the substrate contact electrodes 51 is set shallower than the upper side of the photoelectric conversion element PD. As described above, the upper side of the photoelectric conversion element PD is positioned to have a distance of at least 2.5 μm from the second main surface. Accordingly, below the substrate contact electrodes 51, the FDTI 11 is present by a length of 2.5 μm or more.

Since the substrate contact electrodes 51 are arranged as described above, the substrate contact electrodes 51 electrically connect the semiconductor substrate 1, more specifically the channel region 31, to the P-type well 31W. Accordingly, when a charge reading process is performed to the inside of the pixels, the substrate contact electrodes 51 are set at the ground potential through the substrate contacts 72, and thereby prevent kink generation. Further, since the substrate contact electrodes 51 are arranged on the FDTI 11, there is no need to provide a substrate contact electrode inside each of the pixels. Consequently, the element area of the amplification transistor T_{AM} can be set larger.

Next, an explanation will be given of the outline of an operation of the solid-state imaging device having the configuration described above. Light is incident, through the micro-lens and the color filter (both not shown), onto the second main surface side of the semiconductor substrate 1. The photoelectric conversion element PD photoelectrically converts the incident light to a charge corresponding to the light amount, and accumulates the charge in the N-type region 22. Thereafter, when a pixel read instruction is received from the logic part (not shown), the transfer transistor T_{TR} is turned on, and transfers the charge from the N-type region 22 of the photoelectric conversion element PD to the floating diffusion portion 41. Then, the amplification transistor T_{AM} amplifies the charge amount held by the floating diffusion portion 41, and outputs a signal corresponding to the charge amount to the logic part (not shown). When a pixel charge erase instruction is received from the logic part, the reset transistor T_{RS} operates and resets the charge accumulated in the floating diffusion portion 41.

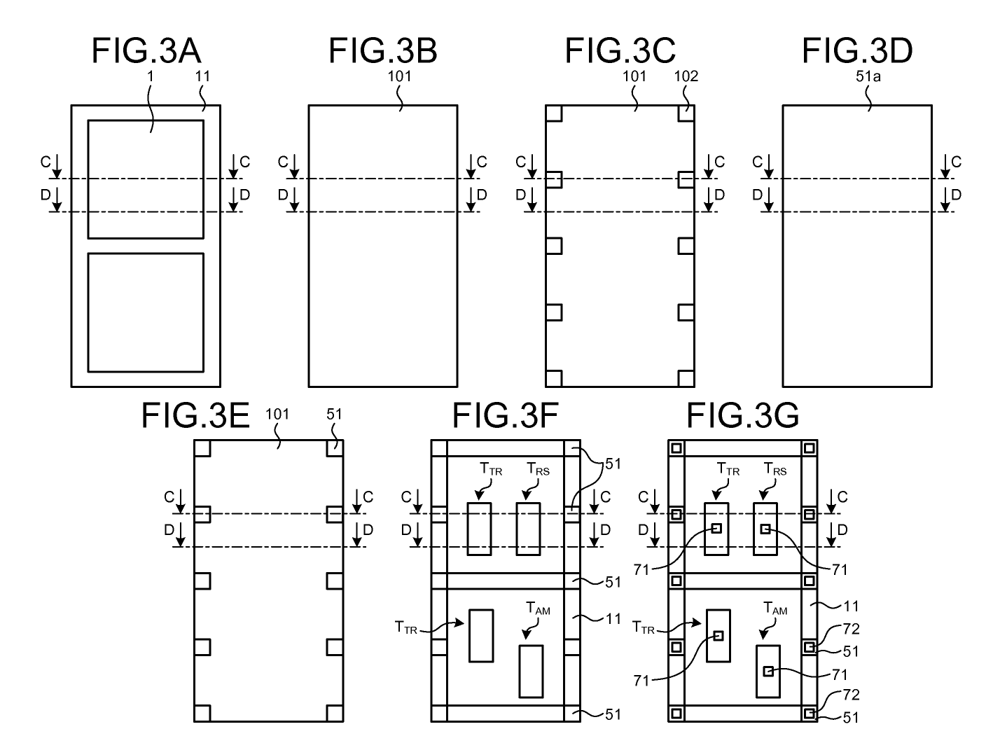

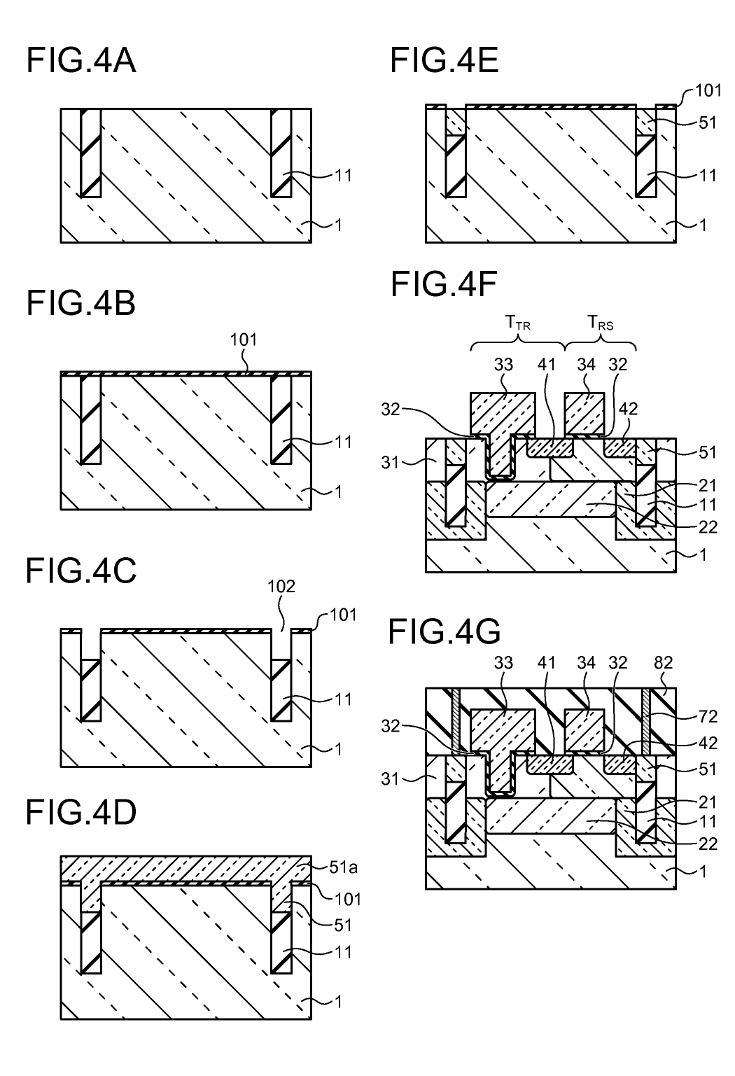

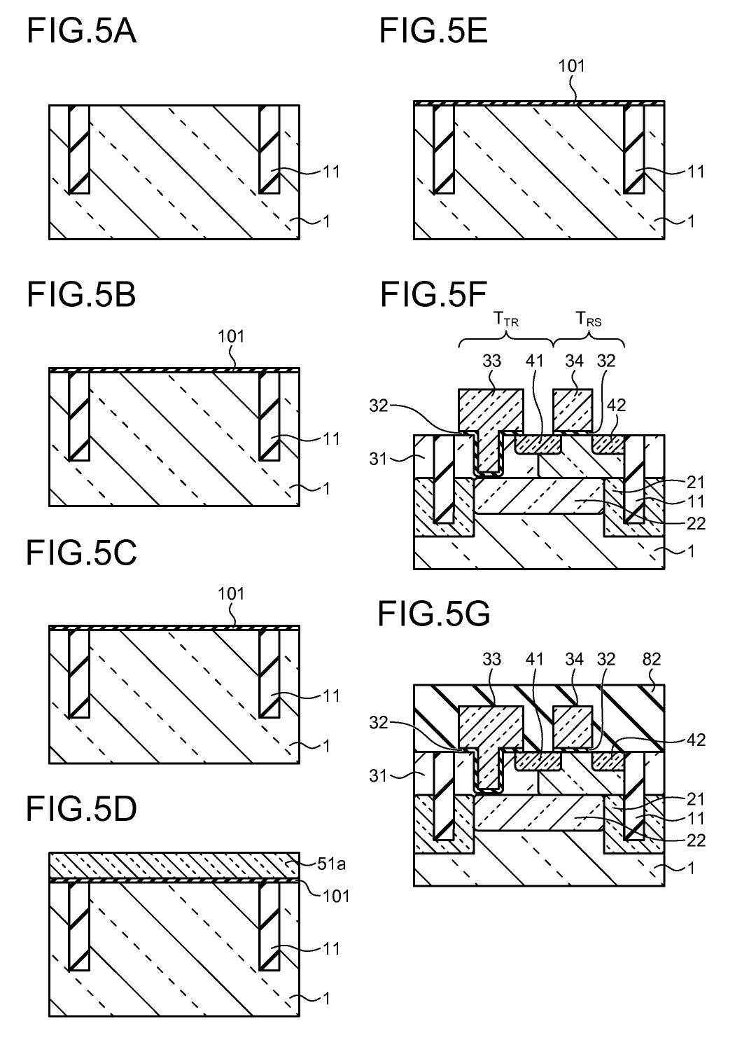

Next, an explanation will be given of a manufacturing method of the solid-state imaging device having the configuration described above. FIGS. 3A to 3G include top views schematically showing an example of a sequence of a manufacturing method of the solid-state imaging device according to the first embodiment. FIGS. 4A to 5G include sectional views schematically showing the example of a sequence of a manufacturing method of the solid-state imaging device according to the first embodiment. FIGS. 4A to 4G include sectional views take along a line C-C in FIGS. 3A to 3G, and FIGS. 5A to 5G include sectional views take along a line D-D in FIGS. 3A to 3G.

At first, as shown in FIGS. 3A, 4A and 5A, the FDTI is formed to have a predetermined depth from the first main surface side of the semiconductor substrate 1. For example, a mask film having openings at regions for forming the FDTI 11 is formed on the first main surface side of the semiconductor substrate 1. Then, trenches are formed to have a predetermined depth in the semiconductor substrate 1 by use of anisotropic etching, such as an RIE (Reactive Ion Etching) method, while the mask film is used as a mask. Then, a silicon oxide film is embedded in the trenches. For example, a TEOS (Tetraethyl orthosilicate) film is formed by use of an LPCVD (Low Pressure Chemical Vapor Deposition) method to embed a silicon oxide film in the trenches. Then, the part of the silicon oxide film protruding upward from the upper side of the semiconductor substrate 1 is removed by polishing by use of a CMP (Chemical Mechanical Polishing) method. The mask film is also removed.

Thereafter, as shown in FIGS. 3B, 4B and 5B, a stopper film 101 is formed all over on the first main surface of the semiconductor substrate 1 including the FDTI 11 formed therein. The stopper film 101 may be formed of a multilayer film of a silicon oxide film and a silicon nitride film.

Thereafter, a resist is applied onto the stopper film 101. Then, a resist pattern is formed by use of a lithography technique, such that the resist pattern has openings at positions for forming the substrate contact electrodes, i.e., substrate contact electrodes 51. Then, the stopper film 101 and the FDTI 11 are etched by use of anisotropic etching, while the resist pattern is used as a mask. Consequently, as shown in FIGS. 3C, 4C and 5C, trenches 102 are formed. The trenches 102 are formed by removing parts of the silicon oxide film on the upper side of the FDTI 11.

Thereafter, as shown in FIGS. 3D, 4D and 5D, a P-type poly-silicon film 51a is formed all over on the first main surface of the semiconductor substrate 1 to embed the trenches 102. This poly-silicon film 51a is obtained by forming a poly-silicon film doped with a P-type impurity, such as boron, by use of a film preparation method, such as a CVD method. Alternatively, the poly-silicon film 51a may be obtained by forming an intrinsic poly-silicon film by use of a film preparation method, such as a CVD method, and then doping this film with a P-type impurity, such as boron, by use of an ion implantation method, plasma doping method, or solid phase diffusion method.

Thereafter, as shown in FIGS. 3E, 4E and 5E, the part of the poly-silicon film 51a deposited above the first main surface of the semiconductor substrate 1 is removed by planarization by use of a CMP method. Alternatively, the part of the poly-silicon film 51a deposited above the first main surface of the semiconductor substrate 1 may be removed by etching-back by use of an etching technique, such as an RIE method. At this time, the polishing or etching-back of the poly-silicon film 51a is finished when the stopper film 101 is exposed. Thus, the stopper film 101 serves as a stopper in removing part of the poly-silicon film 51a. Consequently, the poly-silicon film 51a is embedded in the trenches 102, so that the substrate contact electrodes 51 are formed.

Thereafter, as shown in FIGS. 3F, 4F and 5F, the stopper film 101 is removed, and elements in each of the pixels are fabricated. For example, the photoelectric conversion element PD is provided, such that the P-type region 21 is formed within a range of a predetermined depth around the FDTI 11, and the N-type region 22 is formed within a range of a predetermined depth as a portion surrounded by the P-type region 21. For example, the P-type region 21 and the N-type region 22 are formed by implanting ions of a P-type impurity and ions of an N-type impurity respectively into predetermined regions by use of an ion implantation method and then performing activation of the impurities. Further, the P-type well 31W is formed at a region for forming the reset transistor T_{RS}. Thereafter, the trench 30 is formed at the region for forming the reset transistor T_{RS}, and the gate insulating film 32 is formed on the first main surface of the semiconductor substrate 1. At this time, the gate insulating film 32 is formed to cover the inside of the trench 30. Then, a conductive film is formed on the first main surface of the semiconductor substrate 1 to fill the trench 30 covered with the gate insulating film 32. Then, the conductive film and the gate insulating film 32 are processed by use of a lithography technique and an etching technique. Consequently, the gate electrode 33 of the transfer transistor T_{TR}, the gate electrode (not shown) of the amplification transistor T_{AM}, and the gate electrode 34 of the reset transistor T_{RS} are formed. Then, the floating diffusion portion 41 and the N-type region 42 are formed at predetermined regions on the first main surface side of the semiconductor substrate 1 by use of, for example, an ion implantation method.

Thereafter, as shown in FIGS. 3G, 4G and 5G, an interlayer insulating film 82 is formed on the first main surface of the semiconductor substrate 1 including the elements formed as described above. Then, contact holes are formed in the interlayer insulating film 82 such that they reach the element electrodes and the substrate contact electrodes 51. Then, a conductive material is embedded in the contact holes to form the contacts 71 connected to the element electrodes and to form the substrate contacts 72 connected to the substrate contact electrodes 51. It should be noted that the interlayer insulating film 82 and the contacts formed on the element diffusion regions are not shown in FIG. 3G.

Thereafter, the semiconductor substrate 1 is polished from the second main surface side until the semiconductor substrate 1 comes to have a predetermined thickness. In this example, the polishing is performed until the FDTI 11 is exposed. For example, a CMP method is used for this polishing. Then, the color filter and the micro-lens are provided to each of the pixels on the second main surface side of the semiconductor substrate 1. With the processes described above, the solid-state imaging device according to the first embodiment is obtained.

According to the first embodiment, the upper side of the FDTI 11 partitioning the pixels is partly removed, and a semiconductor film is embedded at the removed positions, to form the substrate contact electrodes 51. Then, the substrate contacts 72 are formed to be electrically connected to the substrate contact electrodes 51. Consequently, the substrate contact electrodes 51 are electrically connected to the semiconductor substrate 1 via regions other than the pixels, so that the potential of each of the pixels is fixed by the substrate contacts 72. Thus, there is provided an effect that realizes an arrangement of the substrate contact electrodes in the solid-state imaging device of the rear incident type to prevent a decrease in the areas of the other elements while preventing color mixing. For example, the area of the amplification transistor T_{AM} can be set larger to reduce the random noise.

### Second Embodiment

In the first embodiment, the active regions are provided as parts of the FDTI on the first main surface side. The second embodiment will be explained in a case where an FDTI is formed of a metal film.

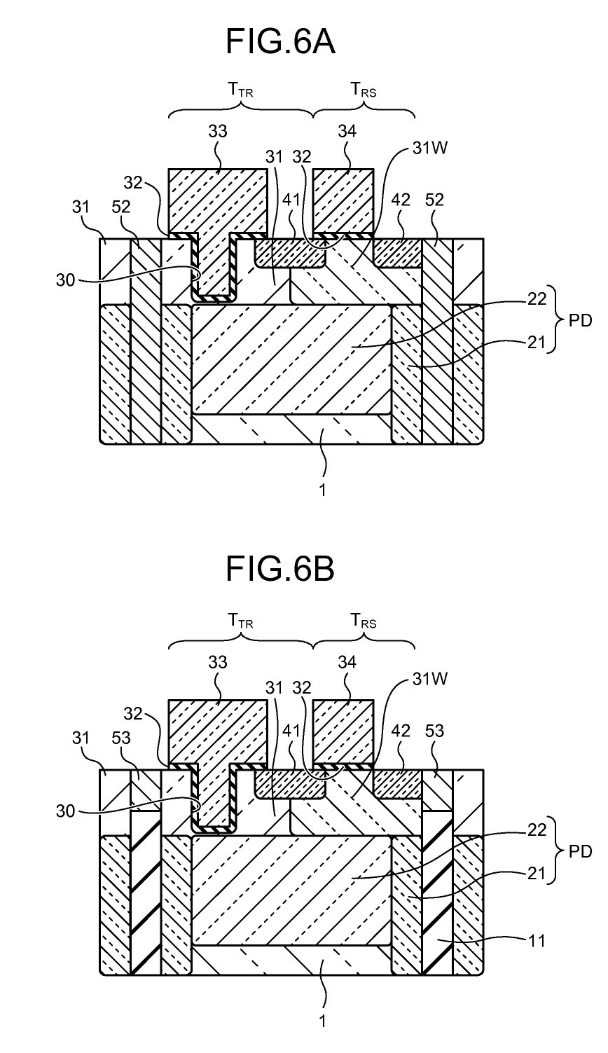

FIGS. 6A and 6B include sectional views schematically showing an example of a solid-state imaging device according to the second embodiment. For example, FIGS. 6A and 6B are sectional views taken along the line A-A in FIG. 1. In the second embodiment, an FDTI is entirely or partly formed of a metal film. FIG. 6A shows an example where an FDTI 52 is entirely formed of a metal film. FIG. 6B shows an example where an FDTI 11 is partly replaced with a metal film 53. In FIG. 6B, the active regions serving as the substrate contact electrodes 51 according to the first embodiment are replaced with the metal films 53. In other words, the metal films 53 serve as substrate contact electrodes. The other parts of the configuration are the same as those explained in the first embodiment, and so their descriptions will be omitted.

As shown in FIG. 6A, in a case where the FDTI 52 is entirely formed of a metal film, the refractive index of the metal film forming the FDTI 52 differs from the refractive index of the semiconductor substrate 1. Accordingly, the FDTI 52 is electrically connected to the semiconductor substrate 1 while preventing color mixing between adjacent pixels within a range where the FDTI 52 is formed. In this case, substrate contacts 72 are provided on the FDTI 52 to prevent kink generation when a charge reading process is performed to the inside of the pixels. Further, as shown in FIG. 6B, in a case where the FDTI 11 is partly formed of the metal film 53, the metal film 53 is electrically connected to the semiconductor substrate 1, as in the first embodiment. Accordingly, when a charge reading process is performed to the inside of the pixels, the substrate contacts 72 are set at the ground potential, and thereby prevent kink generation.

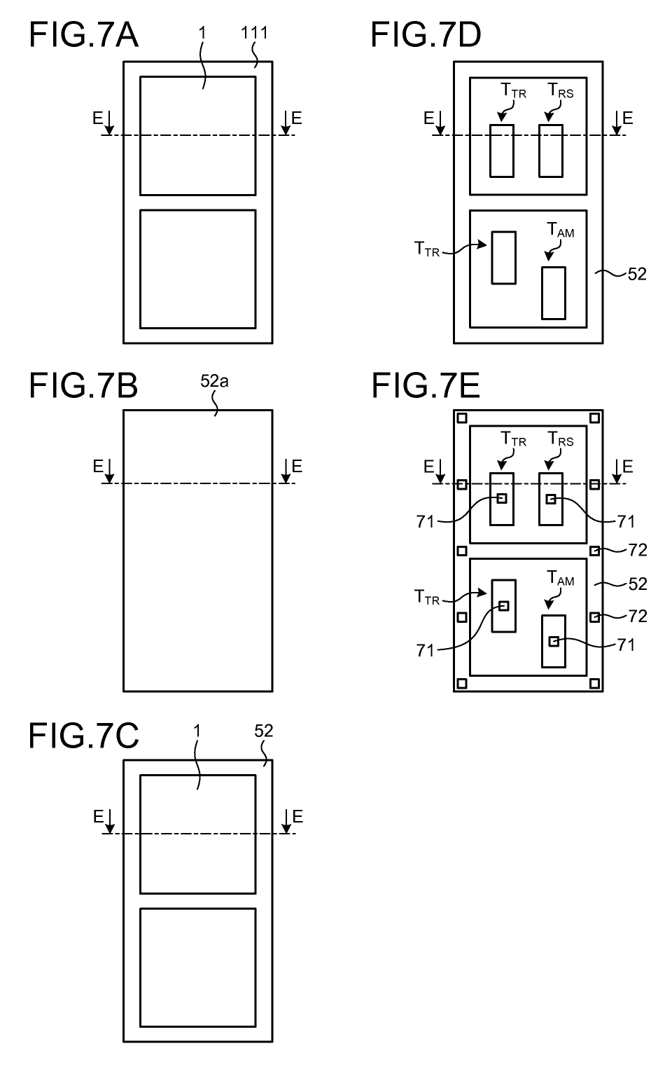

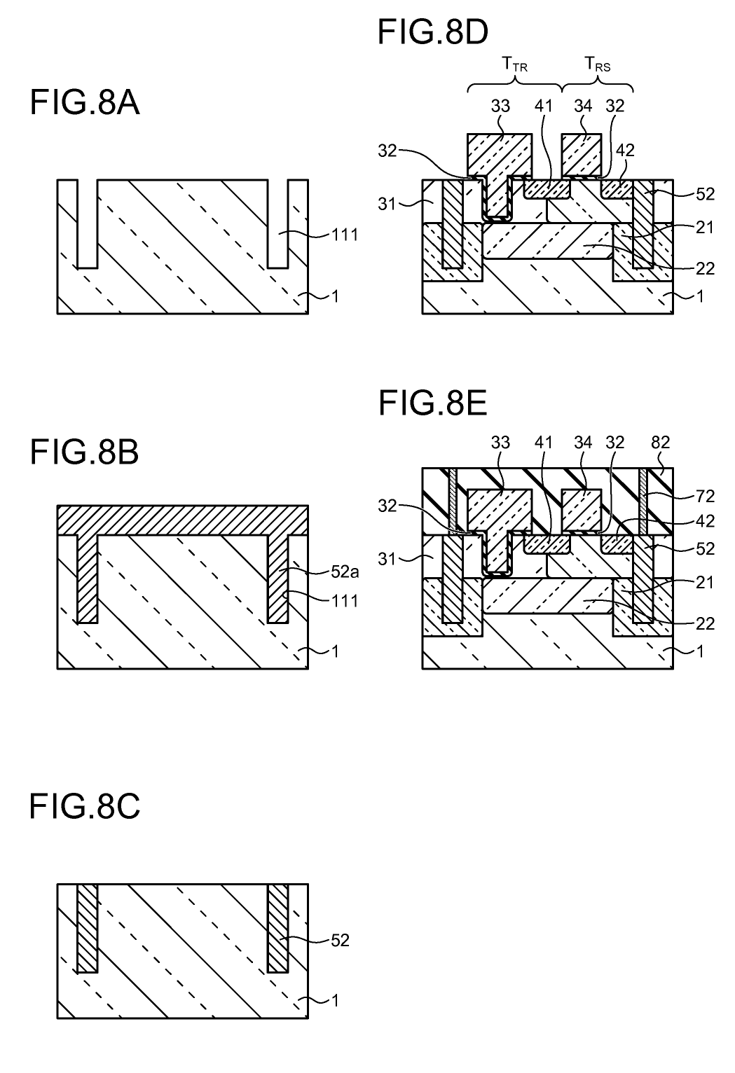

Next, an explanation will be given of a manufacturing method of the solid-state imaging device having the configuration described above. FIGS. 7A to 7E include top views schematically showing an example of a sequence of a manufacturing method of a solid-state imaging device, in which an FDTI is entirely formed of a metal film, according to the second embodiment. FIGS. 8A to 8E include sectional views schematically showing the example of a sequence of a manufacturing method of a solid-state imaging device, in which an FDTI is entirely formed of a metal film, according to the second embodiment. FIGS. 8A to 8E include sectional views take along a line E-E in FIGS. 7A to 7E.

At first, as shown in FIGS. 7A and 8A, trenches 111 are formed to have a predetermined depth from the first main surface side of the semiconductor substrate 1. For example, a mask film (not shown) having openings at regions for forming the FDTI 52 is formed on the first main surface side of the semiconductor substrate 1. Then, the trenches 111 are formed to have a predetermined depth in the semiconductor substrate 1 by use of anisotropic etching, such as an RIE method, while the mask film is used as a mask. Then, the mask film is removed.

Thereafter, as shown in FIGS. 7B and 8B, a metal film 52a is formed all over on the first main surface of the semiconductor substrate 1 including the trenches 111 formed therein. At this time, the metal film 52a is formed to fill the trenches 111 with the metal film 52a. For example, the metal film may be made of tungsten, molybdenum, tungsten silicide, or molybdenum silicide.

Thereafter, as shown in FIGS. 7C and 8C, the part of the metal film 52a above the first main surface of the semiconductor substrate 1 is removed by polishing by use of a CMP method. This polishing is finished when the first main surface of the semiconductor substrate 1 is exposed. Consequently, the FDTI 52 is formed such that it includes the trenches 111 and the metal film 52a embedded therein.

Thereafter, as shown in FIGS. 7D and 8D, elements in each of the pixels are fabricated. The process for this is the same as that of the first embodiment explained with reference to FIGS. 3F, 4F and 5F.

Thereafter, as shown in FIGS. 7E and 8E, an interlayer insulating film 82 is formed on the first main surface of the semiconductor substrate 1 including the elements formed as described above. Then, contact holes are formed in the interlayer insulating film 82 such that they reach the element electrodes and the FDTI 52. Then, a conductive material is embedded in the contact holes to form the contacts 71 connected to the element electrodes and to form the substrate contacts 72 connected to the FDTI 52. It should be noted that the interlayer insulating film 82 and the contacts formed on the element diffusion regions are not shown in FIG. 7E.

Thereafter, the semiconductor substrate 1 is polished from the second main surface side until the semiconductor substrate 1 comes to have a predetermined thickness. At this time, the polishing is performed until the FDTI 52 is exposed. For example, a CMP method is used for this polishing. Then, a color filter and a micro-lens are provided to each of the pixels on the second main surface side of the semiconductor substrate 1. With the processes described above, the solid-state imaging device including the FDTI 52 entirely formed of a metal is obtained.

The solid-state imaging device shown in FIG. 6B, may be manufactured by a method almost the same as the method shown in FIGS. 3A to 5G according to the first embodiment. However, in FIGS. 3D, 4D and 5D, the method differs in that, in place of the P-type poly-silicon film 51a, the metal film 52a is embedded in the trenches 102.

The second embodiment can provide the same effects as the first embodiment.

### Third Embodiment

The first embodiment is explained in a case where the upper side of the FDTI is partly removed and the active regions are provided at the removed positions. The second embodiment is explained in a case where the FDTI is partly or entirely replaced with the metal films. These replacing active regions or metal films are connected to the substrate contact. The third embodiment will be explained in another case where substrate contacts are used in common for pixels adjacent to each other.

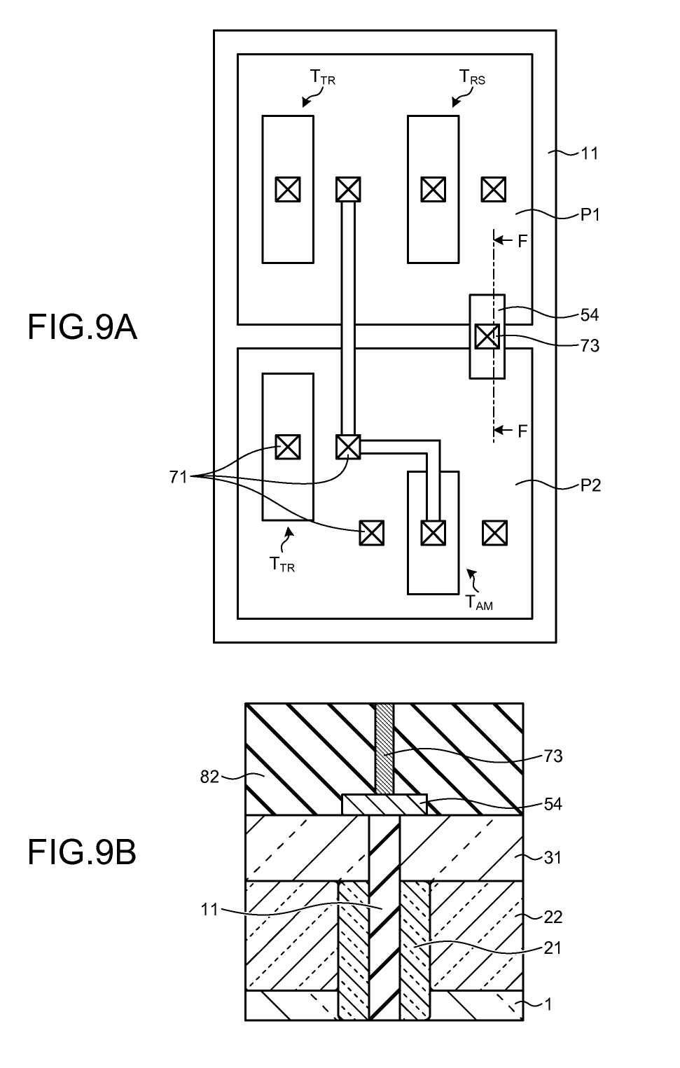

FIGS. 9A and 9B include views schematically showing an example of a configuration of a solid-state imaging device according to the third embodiment, in which FIG. 9A is a top view showing an example of its layout, and FIG. 9B is a sectional view taken along a line F-F in FIG. 9A. As shown in FIGS. 9A and 9B, a substrate contact electrode 54 made of a conductive film is arranged to straddle the part of the FDTI 11 present between two pixels P1 and P2 adjacent to each other and to come into contact with the semiconductor substrate 1 in each of the pixels P1 and P2. A substrate contact 73 is provided on and connected to the substrate contact electrode 54. The substrate contact electrode 54 may be formed of a semiconductor film, such as a poly-silicon film doped with a P-type impurity or an N-type impurity, or a metal film, such as a film of aluminum, titanium, titanium nitride, tungsten, molybdenum, tungsten silicide, or molybdenum silicide.

As described above, since the substrate contact electrode 54 is arranged to bridge the two pixels P1 and P2, the installation area for the substrate contact electrode 54 can be reduced as compared with a case where substrate contact electrodes 54 are respectively and separately provided to the pixels P1 and P2. The other parts of the configuration are the same as those of the first embodiment, and so their descriptions will be omitted.

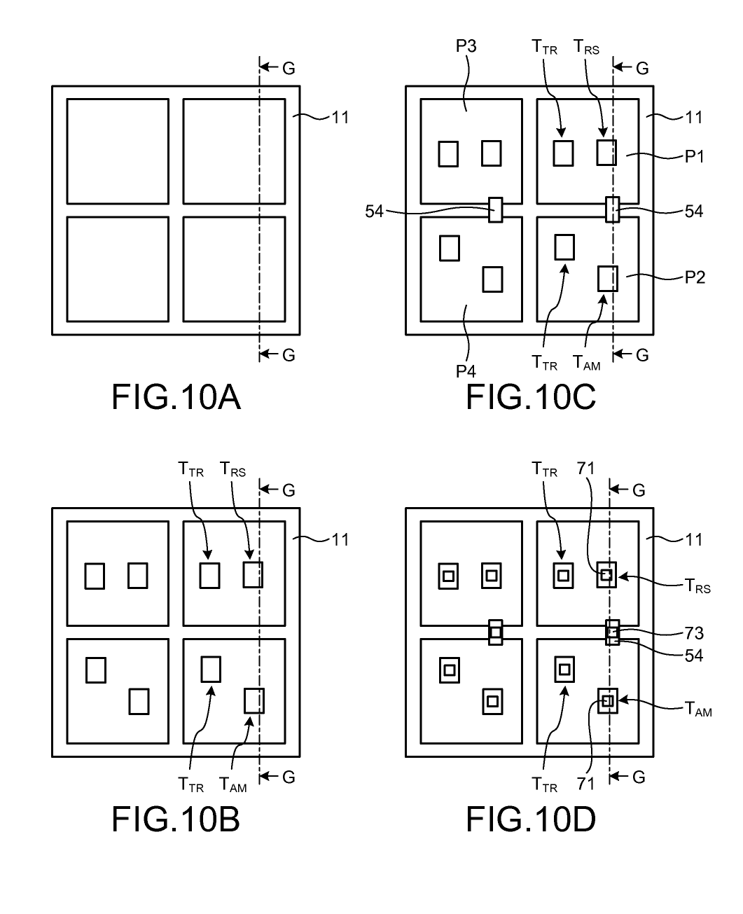

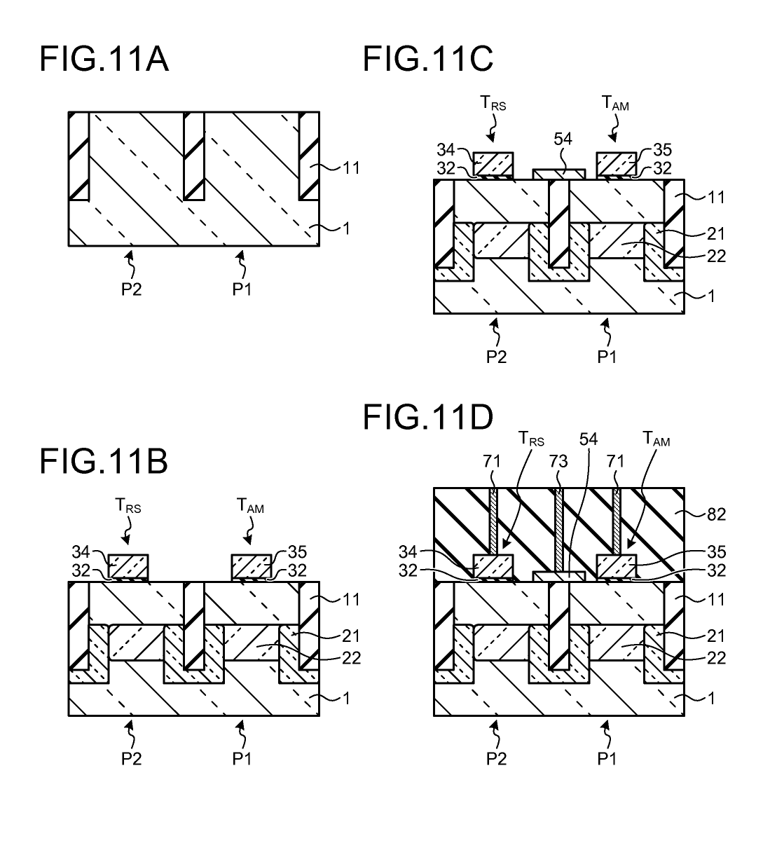

Next, an explanation will be given of a manufacturing method of the solid-state imaging device having the configuration described above. FIGS. 10A to 1D include top views schematically showing an example of a sequence of a manufacturing method of the solid-state imaging device according to the third embodiment. FIGS. 11A to 11D include sectional views schematically showing the example of a sequence of a manufacturing method of the solid-state imaging device according to the third embodiment. FIGS. 11A to 11D include sectional views take along a line G-G in FIGS. 10A to 11D.

At first, as shown in FIGS. 10A and 11A, an FDTI 11 is formed to have a predetermined depth from the first main surface side of the semiconductor substrate 1. The process for this is the same as that of the first embodiment explained with reference to FIGS. 3A, 4A and 5A.

Thereafter, as shown in FIGS. 10B and 11B, elements in each of the pixels are fabricated on the first main surface side of the semiconductor substrate 1 including the FDTI 11 formed therein. The process for this is the same as that of the first embodiment explained with reference to FIGS. 3F, 4F and 5F.

Thereafter, as shown in FIGS. 10C and 11C, insulating films formed on the first main surface of the semiconductor substrate 1 in the preceding steps are removed by use of anisotropic etching, such as an RIE method. Then, for example, a conductive film is formed on the first main surface of the semiconductor substrate 1 by use of a film formation method, such as a sputtering method. Then, a resist is applied onto the conductive film. Then, a resist pattern is formed by use of a lithography technique, such that the resist pattern provides a shape that straddles the part of the FDTI 11 present between the two pixels P1 and P2 adjacent to each other and comes into contact with the upper side of the semiconductor substrate 1 in each of the two pixels P1 and P2. Then, patterning of the conductive film is performed by use of anisotropic etching, such as an RIE method, while the resist pattern is used as a mask. Consequently, the substrate contact electrodes 54 are formed.

Thereafter, as shown in FIGS. 10D and 11D, an interlayer insulating film 82 is formed on the first main surface of the semiconductor substrate 1 including the elements formed as described above. Then, contact holes are formed in the interlayer insulating film 82 such that they reach the element electrodes and the substrate contact electrodes 54. Then, a conductive material is embedded in the contact holes to form the contacts 71 connected to the element electrodes and to form the substrate contacts 73 connected to the substrate contact electrodes 54. It should be noted that the interlayer insulating film 82 and the contacts formed on the element diffusion regions are not shown in FIG. 10D.

Thereafter, the semiconductor substrate 1 is polished from the second main surface side until the semiconductor substrate 1 comes to have a predetermined thickness. At this time, the polishing is performed until the FDTI 11 is exposed. For example, a CMP method is used for this polishing. Then, a color filter and a micro-lens are provided to each of the pixels on the second main surface side of the semiconductor substrate 1. With the processes described above, the solid-state imaging device according to the third embodiment is obtained.

The third embodiment can provide the same effects as the first embodiment.

### Fourth Embodiment

The first and second embodiments are explained in a case where the substrate contact electrodes are arranged at the upper side of the FDTI. The fourth embodiment will be explained in a case where some elements used in common for two pixels adjacent to each other are arranged on the FDTI.

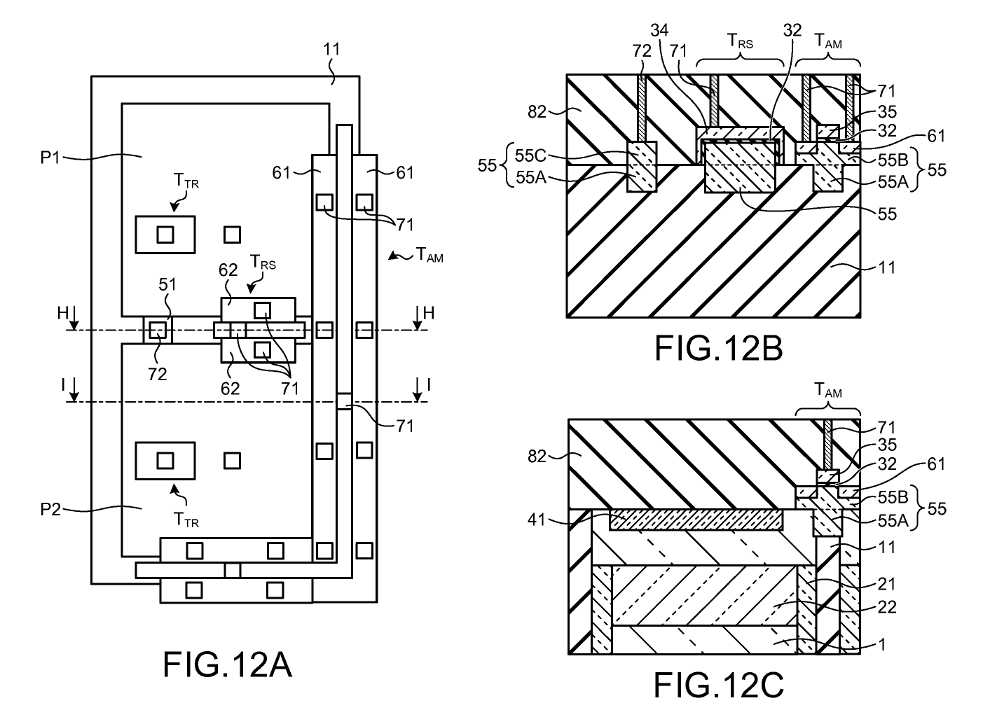

FIGS. 12A to 12C include views schematically showing an example of a configuration of a solid-state imaging device according to the fourth embodiment, in which FIG. 12A is a top view showing an example of its layout, FIG. 12B is a sectional view taken along a line H-H in FIG. 12A, and FIG. 12C is a sectional view taken along a line I-I in FIG. 12A. As shown in FIGS. 12A to 12C, a transfer transistor T_{TR} is provided in each of two pixels P1 and P2 adjacent to each other. Further, an amplification transistor T_{AM}, a reset transistor T_{RS}, and substrate contact electrodes 51 are arranged on the FDTI 11 of the two pixels P1 and P2 adjacent to each other, and are used in common for these pixels. More specifically, the reset transistor T_{RS} and the substrate contact electrodes 51 are arranged on the part of the FDTI 11 partitioning the pixels P1 and P2. The amplification transistor T_{AM} is arranged on the part of the FDTI 11 continuously present along the pixels P1 and P2 and partitioning the outer periphery of the pixels P1 and P2. The amplification transistor T_{AM} has an element area larger than that of the reset transistor T_{RS}. In the example shown in FIG. 12A, the amplification transistor T_{AM} is formed in an L-shape along three sides of the FDTI 11 partitioning the pixels.

The amplification transistor T_{AM} and the reset transistor T_{RS} are arranged on active regions 55 formed at a region including the upper side of the FDTI 11. Each of the active regions 55 comprises two active regions 55A and 55B. The active region 55A is formed by replacing the upper side of the element isolation film of the FDTI 11 with a semiconductor film. Accordingly, the active region 55A has a width almost the same as that of the FDTI 11. In this respect, the widths of the active region 55A and the FDTI 11 are defined in a direction perpendicular to their depth (height) direction in a plane perpendicular to their extending direction.

The active region 55B is formed of a semiconductor film arranged to be connected to the active region 55A on the first main surface of the semiconductor substrate 1. The active region 55B has a width larger than that of the active region 55A. Also in this case, the width of the active region 55B is defined in a direction perpendicular to its depth (height) direction in a plane perpendicular to its extending direction.

The amplification transistor T_{AM} includes a gate electrode 35 arranged through a gate insulating film 32 on a portion of the active region 55B near the center in the width direction. The gate insulating film 32 and the gate electrode 35 are formed along the active region 55B. Further, source/drain regions 61 are formed on the opposite sides of the active region 55B with the gate electrode 35 interposed therebetween in the width direction.

The reset transistor T_{RS} includes a gate electrode 34 arranged through a gate insulating film 32 on a portion of the active region 55B near the center in the width direction. The gate insulating film 32 and the gate electrode 34 are formed along the active region 55B. Further, source/drain regions 62 are formed on the opposite sides of the active region 55B with the gate electrode 34 interposed therebetween in the width direction.

Each of the substrate contact electrodes 51 comprises two active regions 55A and 55C. The active region 55A is formed by replacing the upper side of the FDTI 11 with a semiconductor film. Accordingly, the active region 55A has a width almost the same as that of the FDTI 11. The active region 55C is formed of a semiconductor film arranged to be connected to the active region 55A on the first main surface of the semiconductor substrate 1. The active region 55C has a width almost the same as that of the active region 55A. Also in this case, the width of the active region 55C is defined in a direction perpendicular to its depth (height) direction in a plane perpendicular to its extending direction.

A photoelectric conversion element PD is formed at a predetermined depth in each of the pixels P1 and P2. The photoelectric conversion element PD is the same as that explained in the first embodiment. Further, a floating diffusion portion 41 is formed in an area to be the drain region of the transfer transistor T_{TR} above the photoelectric conversion element PD in each of the pixels P1 and P2.

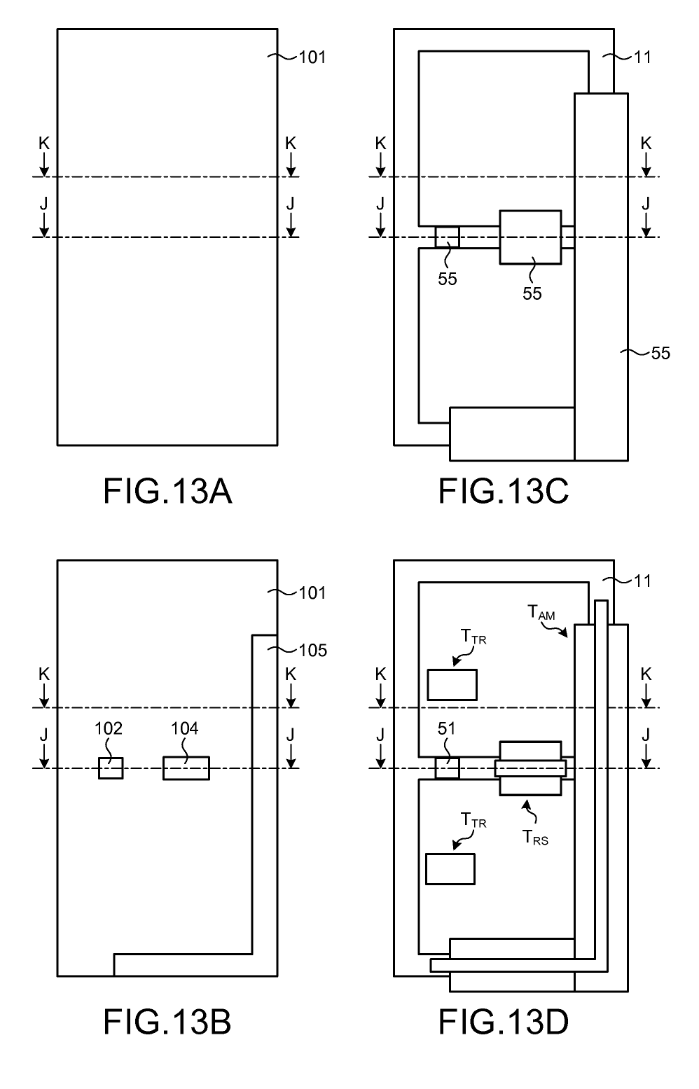

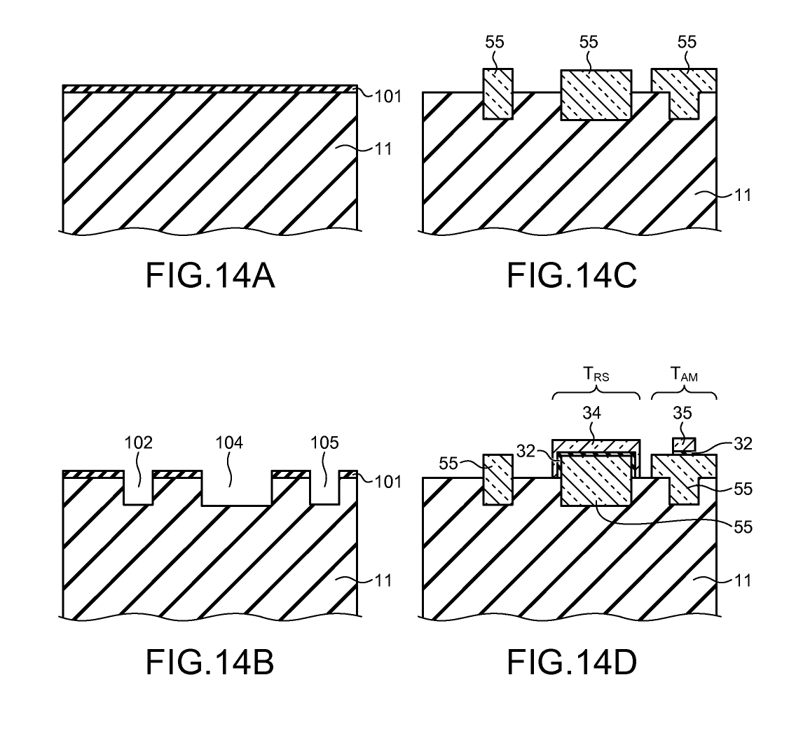

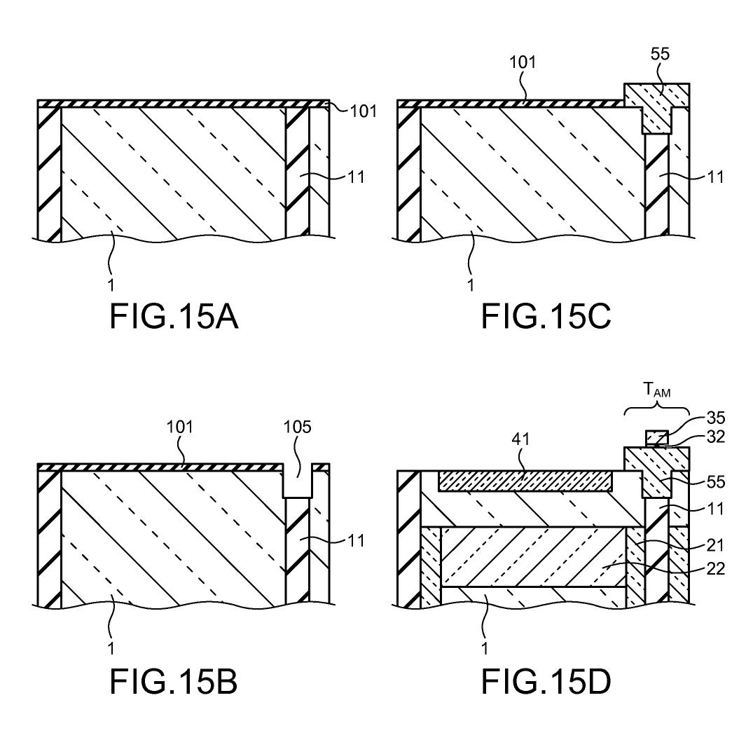

Next, an explanation will be given of a manufacturing method of the solid-state imaging device having the configuration described above. FIGS. 13A to 13D include top views schematically showing an example of a sequence of a manufacturing method of the solid-state imaging device according to the fourth embodiment. FIGS. 14A to 15D include sectional views schematically showing the example of a sequence of a manufacturing method of the solid-state imaging device according to the fourth embodiment. FIGS. 14A to 14D include sectional views taken along a line J-J in FIGS. 13A to 13D, and FIGS. 15A to 15D include sectional views taken along a line K-K in FIGS. 13A to 13D.

At first, as shown in FIGS. 13A, 14A and 15A, an FDTI 11 is formed to have a predetermined depth from the first main surface side of the semiconductor substrate 1. The process for this is the same as that of the first embodiment explained with reference to FIGS. 3A, 4A and 5A. Further, a stopper film 101 is formed all over on the first main surface of the semiconductor substrate 1.

Thereafter, as shown in FIGS. 13B, 14B and 15B, the FDTI 11 is partly removed from the first main surface side to a predetermined depth, at regions for forming the substrate contact electrodes 51, the amplification transistor T_{AM}, and the reset transistor T_{RS}. For example, a resist is applied onto the first main surface of the semiconductor substrate 1. Then, a resist pattern is formed by use of a lithography technique, such that the resist pattern has openings at regions for forming the substrate contact electrodes 51, the amplification transistor T_{AM}, and the reset transistor T_{RS}. Then, the FDTI 11 is etched to a predetermined depth by use of an etching technique, while the resist pattern is used as a mask. Consequently, trenches 102 are formed at positions for forming the substrate contact electrodes 51, and trenches 104 and 105 are formed respectively at positions for forming the reset transistor T_{RS} and the amplification transistor T_{AM}.

Thereafter, an amorphous silicon film is deposited on the first main surface of the semiconductor substrate 1 by use of a film preparation technique, such as a CVD method. At this time, the amorphous silicon film is deposited to fill the trenches 102, 104, and 105. Further, the amorphous silicon film is deposited such that its upper side is present above the first main surface of the semiconductor substrate 1. It may be modified such that the stopper film 101 is partly removed at regions adjacent to the trenches 104 and 105 before the amorphous silicon film is deposited. Consequently, the amorphous silicon film is set in contact with the first main surface of the semiconductor substrate 1 at regions adjacent to the trenches 104 and 105.

Then, the amorphous silicon film is planarized by polishing by use of a CMP method. Then, a resist is applied onto the amorphous silicon film. Then, a resist pattern is formed by use of a lithography technique, such that the resist pattern masks regions for forming the substrate contact electrodes 51, the amplification transistor T_{AM}, and the reset transistor T_{RS}. Then, the amorphous silicon film is etched by use of an etching technique, such as an RIE method, while the resist pattern is used as a mask. At this time, the etching is performed until the stopper film 101 formed on the first main surface of the semiconductor substrate 1 is exposed. Then, a heat process is performed to the semiconductor substrate 1. This heat process causes solid phase growth that uses, as a seed, the semiconductor substrate 1 with the amorphous silicon film exposed in the trenches 102, 104, and 105, and thereby improves the crystallinity of the silicon film. Consequently, as shown in FIGS. 13C, 14C and 15C, the amorphous silicon film is turned into a crystallized poly-silicon film, so that the active regions 55 are formed. The active regions 55 formed in the trenches 102 serve as the substrate contact electrodes 51.

Thereafter, as shown in FIGS. 13D, 14D and 15D, the stopper film 101 on the first main surface of the semiconductor substrate 1 is removed by use of an etching process or the like, and the photoelectric conversion element PD is formed inside the semiconductor substrate 1. In this example, a P-type region 21 is formed within a range of a predetermined depth around the FDTI 11, and an N-type region 22 is formed within a range of a predetermined depth as a portion surrounded by the P-type region 21.

Further, the gate electrodes of the respective transistors are formed. More specifically, trenches are respectively formed at positions for forming the gate electrodes of the transfer transistors T_{TR} of the respective pixels. Then, a gate insulating film 32 is formed on the first main surface of the semiconductor substrate 1. Then, a conductive film is formed on the gate insulating film 32. This conductive film may be formed of a poly-silicon film or metal film. Then, the gate insulating film and the conductive film are patterned into a predetermined shape by use of a lithography technique and an etching technique. At this time, the gate electrode of each of the transfer transistors T_{TR} is formed to be present at a predetermined position including the corresponding one of the trenches. The gate electrode 34 of the reset transistor T_{RS} is formed to be present on the active region 55 formed on the trench 104. The gate electrode 35 of the amplification transistor T_{AM} is formed to be present on the active region 55 formed on the trench 105.

Thereafter, the source/drain regions of the transfer transistor T_{TR}, the amplification transistor T_{AM}, and reset transistor T_{RS} are formed. These source/drain regions include the floating diffusion portion 41. For example, while the gate electrode of each of the transfer transistor T_{TR}, the amplification transistor T_{AM}, and the reset transistor T_{RS} is used as a mask, doping of an impurity of a predetermined conductive type is performed to the regions on the opposite sides of the gate electrode in the gate length direction by use of an ion implantation method or solid phase diffusion method.

Thereafter, as shown in FIGS. 12A to 12C, an interlayer insulating film 82 is formed on the first main surface of the semiconductor substrate 1 including the elements formed as described above. Then, contact holes are formed in the interlayer insulating film 82 such that they reach the element electrodes, the active regions 55, and the substrate contact electrodes 51. Then, a conductive material is embedded in the contact holes to form the contacts 71 connected to the element electrodes and the active regions 55 of the elements and to form the substrate contacts 72 connected to the active regions 55 of the substrate contact electrodes 51.

Thereafter, the semiconductor substrate 1 is polished from the second main surface side until the semiconductor substrate 1 comes to have a predetermined thickness. At this time, the polishing is performed until the FDTI 11 is exposed. For example, a CMP method is used for this polishing. Then, a color filter and a micro-lens are provided to each of the pixels on the second main surface side of the semiconductor substrate 1. With the processes described above, the solid-state imaging device according to the fourth embodiment is obtained.

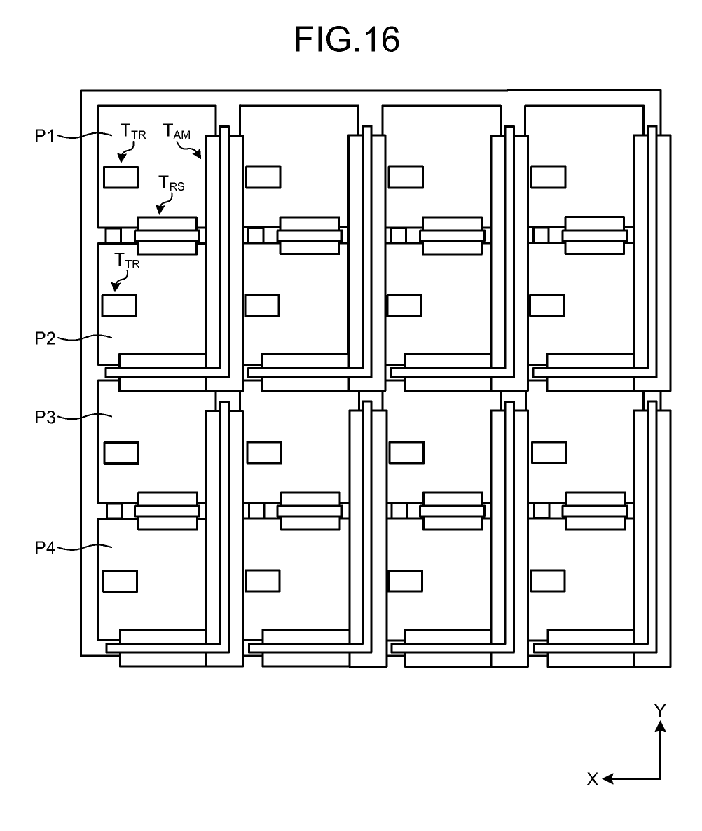

FIG. 16 is a top view schematically showing an example of a pixel element layout. The pixels P1, P2, . . . partitioned by the FDTI 11 are regularly arrayed in an X-direction and a Y-direction perpendicular to the X-direction on the semiconductor substrate 1. In this example, an amplification transistor T_{AM} and a reset transistor T_{RS} are used in common for two pixels adjacent to each other in the Y-direction. Specifically, an amplification transistor T_{AM} and a reset transistor T_{RS} are used in common for the pixel P1 and the pixel P2, and an amplification transistor T_{AM} and a reset transistor T_{RS} are used in common for the pixel P3 and the pixel P4. This is also true of the other pixels. Since the amplification transistor T_{AM} has an L-shape, the element area remains large.

In the example explained above, both of the amplification transistor T_{AM} and the reset transistor T_{RS} are arranged on the FDTI 11. However, only one of them may be arranged on the FDTI 11 and the other one may be arranged in the pixel. This configuration also allows the areas of both of the amplification transistor T_{AM} and the reset transistor T_{RS} to be larger.

Further, in the example explained above, the amplification transistor T_{AM} has an L-shape, but this is a mere example, and this transistor may have another shape. The amplification transistor T_{AM} is arranged on the FDTI 11, so that it is used in common for a plurality of pixels. Accordingly, the amplification transistor T_{AM} may have a linear shape, as long as it can be used in common for a plurality of pixels.

In the fourth embodiment, the upper side of the FDTI 11 is partly removed, and the active regions 55 are formed therein. Then, some elements are arranged on the active regions 55 to bridge a plurality of pixels. Consequently, the elements can be used in common for pixels adjacent to each other, and the element area can remain large. Consequently, the fourth embodiment provides an effect of reducing the random noise in the amplification transistor T_{AM}, for example.

### Fifth Embodiment

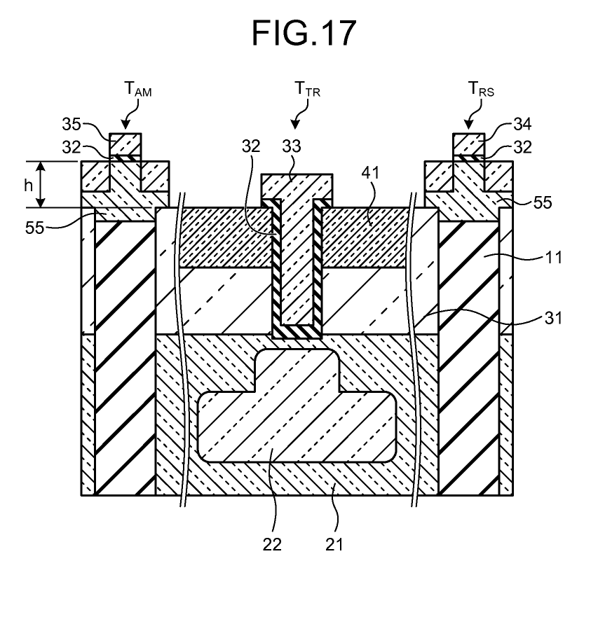

FIG. 17 is a sectional view schematically showing an example of a structure of the solid-state imaging device explained in the fourth embodiment. FIG. 17 provides an illustration to compare a sectional view of the transfer transistor T_{TR} formed on the semiconductor substrate 1 with a sectional view of the amplification transistor T_{AM} and the reset transistor T_{RS} formed on the FDTI 11, and so it does not show an actual sectional view. As shown in FIG. 17, in the fourth embodiment, the upper surface of the active regions 55 where the amplification transistor TAM and the reset transistor TRS are formed is higher by a height “h” than the upper surface of the part of the semiconductor substrate 1 where the transfer transistor TTR is formed. In other words, this brings about a difference “h” in height between the depth of the contact hole formed on the transfer transistor T_{TR} and the depth of the contact holes formed on the amplification transistor T_{AM} and the reset transistor T_{RS}. Accordingly, contact holes may be formed in consideration of this difference “h”. In the fifth embodiment, an explanation will be given of a structure and manufacturing method of a solid-state imaging device that allows the contact holes to be formed without caring about the difference “h”.

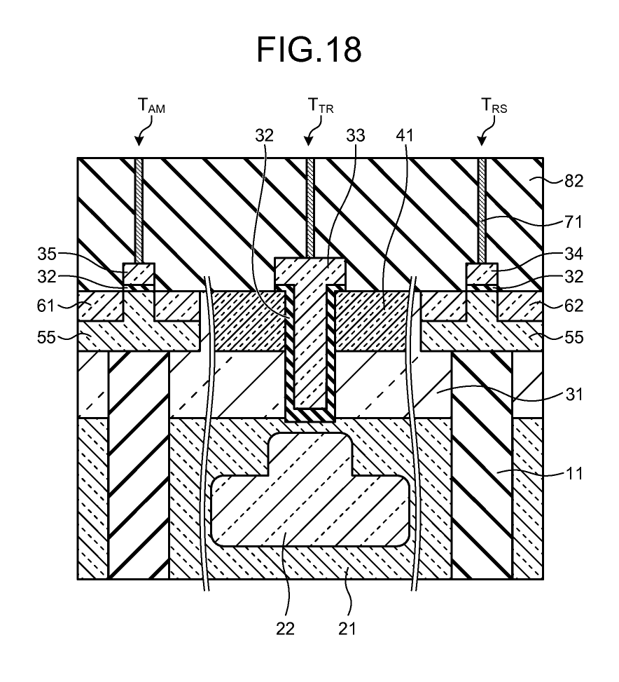

FIG. 18 is a sectional view schematically showing an example of a solid-state imaging device according to the fifth embodiment. As in FIG. 17, FIG. 18 also provides an illustration to compare a sectional view of a transfer transistor T_{TR} formed on a semiconductor substrate 1 with a sectional view of an amplification transistor T_{AM} and a reset transistor T_{RS} formed on an FDTI 11.

As shown in FIG. 18, the upper surface of the active regions 55 is the same in height as the upper surface of the semiconductor substrate 1. Further, along with this feature, the active regions 55 for forming the amplification transistor T_{AM} and the reset transistor T_{RS} have a width larger than the width of the FDTI 11 formed below the active regions 55.

A photoelectric conversion element PD includes a P-type region 21 formed in a predetermined depth between portions of the FDTI 11 and an N-type region 22 formed inside the P-type region 21. The N-type region 22 has a convex shape protruding toward the first main surface side of the semiconductor substrate 1. The other parts of the configuration are the same as those explained in the fourth embodiment, and so their descriptions will be omitted.

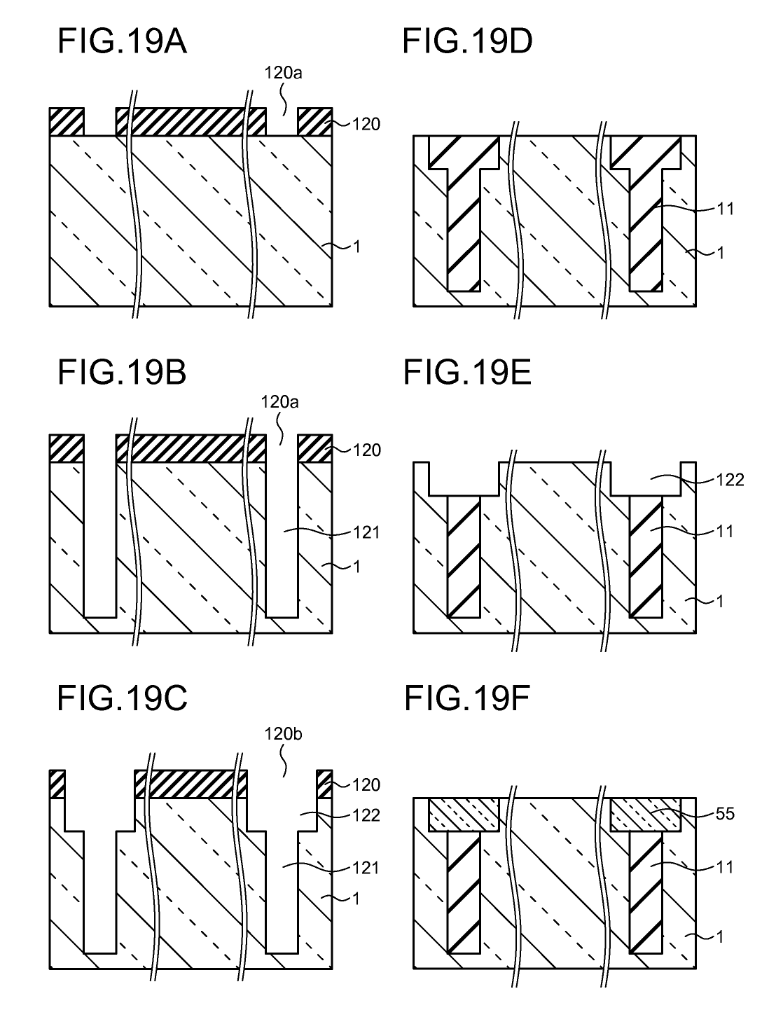

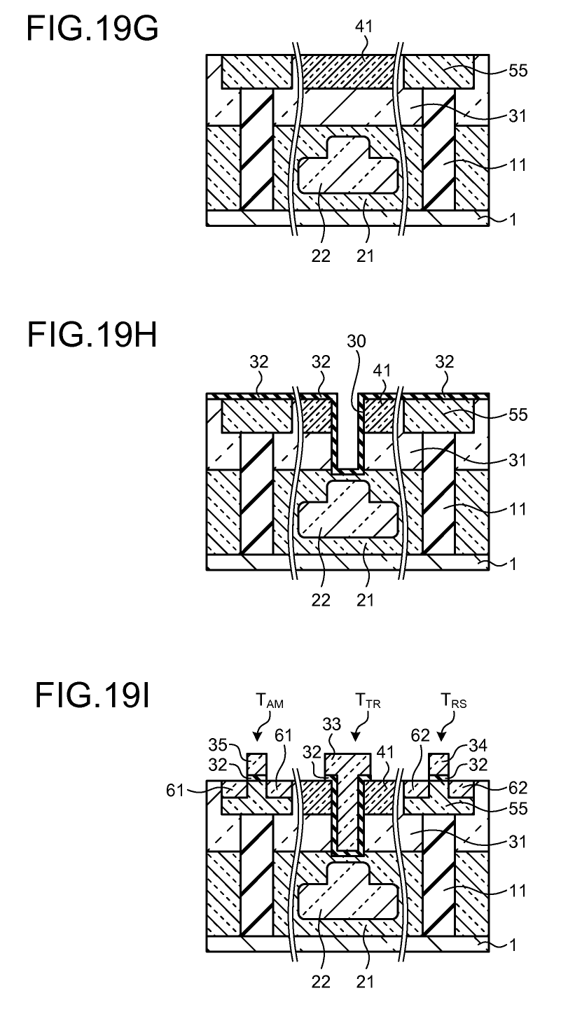

Next, an explanation will be given of a manufacturing method of the solid-state imaging device having the configuration described above. FIGS. 19A to 19I include sectional views schematically showing an example of a sequence of a manufacturing method of the solid-state imaging device according to the fifth embodiment.

At first, as shown in FIG. 19A, a hard mask 120 is formed on the first main surface of the semiconductor substrate 1. The hard mask 120 has openings 120a at positions for forming the FDTI 11. For example, a resist is applied onto the hard mask 120. Then, a resist pattern is formed by patterning the resist by use of a photo-lithography technique, such that the resist pattern has openings at the positions for forming the FDTI 11. Then, the hard mask 120 is etched, while the resist pattern is used as a mask, to form the openings 120a in the hard mask 120. The hard mask 120 may be formed of a silicon oxide film or silicon nitride film.

Thereafter, as shown in FIG. 19B, trenches 121 are formed to have a predetermined depth by use of an etching technique, such as an RIE method, while the hard mask 120 is used as a mask. Then, as shown in FIG. 19C, the hard mask 120 is etched to change part of the openings 120a into openings 120b having a predetermined size. In other words, the openings are enlarged. For example, this etching is performed use of wet etching under conditions to isotropically etch the hard mask 120 only. If the hard mask 120 is formed of a silicon oxide film, a hydrofluoric acid-based solution is used. Alternatively, if the hard mask 120 is formed of a silicon nitride film, a phosphoric acid-based solution is used. Then, the semiconductor substrate 1 is etched by use of an etching technique, such as an RIE method, while the hard mask 120 having the openings 120b is used as a mask. Consequently, trenches 122 are formed on the upper side of the trenches 121, such that the trenches 122 have a larger width in a direction perpendicular to the extending direction of the trenches 121.

Thereafter, as shown in FIG. 19D, a silicon oxide film is embedded in the trenches 121 and 122, and the hard mask 120 is removed. Consequently, the FDTI 11 is formed. For example, a TEOS film is formed by use of an LPCVD method to embed a silicon oxide film in the trenches 121 and 122. Then, the part of the silicon oxide film above the upper side of the semiconductor substrate 1 is removed by polishing by use of a CMP method.

Then, as shown in FIG. 19E, the part of the silicon oxide film embedded in the trenches 122 is removed. For example, this part of the silicon oxide film is removed by use of an etching technique, such as an RIE method, under conditions to hardly etch the semiconductor substrate 1. Consequently, the trenches 122 are formed again on the upper side of the FDTI 11.

Thereafter, as shown in FIG. 19F, an amorphous silicon film is formed on the first main surface of the semiconductor substrate 1 by use of a film preparation technique, such as a CVD method. At this time, the amorphous silicon film is formed to fill the trenches 122. Then, a heat process is performed to the semiconductor substrate 1. This heat process causes solid phase growth that uses, as a seed, the semiconductor substrate 1 with the amorphous silicon film exposed in the trenches 122. Consequently, the amorphous silicon film is turned into a crystallized poly-silicon film.

Thereafter, the part of the poly-silicon film deposited above the first main surface of the semiconductor substrate 1 is removed. For example, this removal of the poly-silicon oxide film may be performed by use of a CMP method or performed by etching-back by use of an anisotropic etching technique. Consequently, the active regions 55 are formed in the trenches 122. The upper surface of the active regions 55 is the same in height as the upper surface of the semiconductor substrate 1.

Thereafter, as shown in FIG. 19G, diffusion regions are formed in each of the pixels. More specifically, the photoelectric conversion element PD is formed inside the semiconductor substrate 1. In this example, a P-type region 21 is formed within a range of a predetermined depth around the FDTI 11, and an N-type region 22 is formed within a range of a predetermined depth as a portion surrounded by the P-type region 21. Further, a floating diffusion portion 41 formed of an N-type diffusion layer is formed at a predetermined region between the active regions 55.

Thereafter, as shown in FIG. 19H, a trench 30 for forming the gate electrode of the transfer transistor T_{TR} is formed in the part of the semiconductor substrate 1 surrounded by the FDTI 11. Then, a gate insulating film 32 is formed on the first main surface of the semiconductor substrate 1. The gate insulating film 32 is formed to cover the sidewall and bottom of the trench 30.

Thereafter, as shown in FIG. 19I, a conductive film is formed on the gate insulating film 32. The conductive film may be formed of a poly-silicon film or metal film. Then, the gate insulating film and the conductive film are patterned into a predetermined shape by use of a lithography technique and an etching technique. At this time, the gate electrode of the transfer transistor T_{TR} is formed to be present at a region including the trench 30. The gate electrode 34 of the reset transistor T_{RS} and the gate electrode 35 of the amplification transistor T_{AM} are formed to be present on the respective active regions 55.

The upper surface of the semiconductor substrate 1 where the transfer transistor T_{TR} is formed is the same in height as the upper surface of the active regions 55 where the amplification transistor T_{AM} and the reset transistor T_{RS} are formed. Accordingly, the upper surfaces of the gate electrodes 33, 34, and 35 of the transfer transistor T_{TR}, the amplification transistor T_{AM}, and the reset transistor T_{RS} are flush with each other.

Thereafter, the source/drain regions 61 and 62 of the amplification transistor T_{AM} and reset transistor T_{RS} are formed. For example, while the gate electrode of each of the amplification transistor T_{AM} and the reset transistor T_{RS} is used as a mask, doping of an impurity of a predetermined conductive type is performed to the regions on the opposite sides of the gate electrode in the gate length direction by use of an ion implantation method or solid phase diffusion method.

Thereafter, as shown in FIG. 18, an interlayer insulating film 82 is formed on the first main surface of the semiconductor substrate 1 including the elements formed as described above. Then, contact holes are formed in the interlayer insulating film 82 such that they reach the element electrodes and the active regions 55. Then, a conductive material is embedded in the contact holes to form the contacts 71 connected to the element electrodes and the active regions 55.

As described above, the upper surface of the semiconductor substrate 1 where the transfer transistor T_{TR} is formed is the same in height as the upper surface of the active regions 55 where the amplification transistor T_{AM} and the reset transistor T_{RS} are formed. Accordingly, the depths of the contact holes connected to the source/drain regions of the respective transistors become equal to each other. Further, the upper surfaces of the gate electrodes 33, 34, and 35 of the transfer transistor T_{TR}, the amplification transistor T_{AM}, and the reset transistor T_{RS} are also the same in height as each other. Accordingly, the depths of the contact holes connected to the gate electrodes 33 to 35 of the respective transistors become equal to each other.

Thereafter, the semiconductor substrate 1 is polished from the second main surface side until the semiconductor substrate 1 comes to have a predetermined thickness. At this time, the polishing is performed until the FDTI 11 is exposed. For example, a CMP method is used for this polishing. Then, a color filter and a micro-lens are provided to each of the pixels on the second main surface side of the semiconductor substrate 1. With the processes described above, the solid-state imaging device according to the fifth embodiment is obtained.

In the fifth embodiment, in a case where elements are arranged on the upper side of the FDTI 11, the active regions 55 for forming the elements are formed on and around the upper side of the FDTI 11, such that the upper surface of the active regions 55 is the same in height as the upper surface of the semiconductor substrate 1. Consequently, the depths of the contact holes formed on the respective elements become equal to each other, and so there is provided an effect of facilitating the control of the depths in forming the contact holes.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid-state imaging device comprising:
an element isolation film embedded in a first trench penetrating a semiconductor substrate from a first main surface to a second main surface;
a photoelectric conversion element embedded in a pixel region isolated by the element isolation film, the photoelectric conversion element including a P-type region formed on the second main surface side along the first trench and an N-type region formed at a region surrounded by the P-type region; and
a transfer transistor formed at the first main surface and configured to transfer a charge of the photoelectric conversion element,
wherein a part of the element isolation film on the first main surface side is formed of an active region.

2. The solid-state imaging device according to claim 1, wherein the active region is connected to a substrate contact that sets the semiconductor substrate at a ground potential.

3. The solid-state imaging device according to claim 1, further comprising an element formed on the active region and configured to perform a predetermined process by use of the charge transferred by the transfer transistor.

4. The solid-state imaging device according to claim 1, wherein a position of the active region at the first main surface side in a height direction is flush with a position of the semiconductor substrate at the first main surface side in the height direction.

5. The solid-state imaging device according to claim 2, wherein
a plurality of pixels are arrayed on the semiconductor substrate and isolated from each other by the element isolation film, and
the active region is shared by adjacent pixels of the pixels, which are adjacent to each other with the active region interposed therebetween.

6. The solid-state imaging device according to claim 5, wherein the active region is present at a point between the adjacent pixels of the pixels.

7. The solid-state imaging device according to claim 3, wherein
a plurality of pixels are arrayed on the semiconductor substrate and isolated from each other by the element isolation film, and
the element is shared by adjacent pixels of the pixels, which are adjacent to each other.

8. The solid-state imaging device according to claim 7, wherein the element is formed on the active region continuously arranged along an outer periphery of pixel regions of the adjacent pixels.

9. The solid-state imaging device according to claim 7, wherein
the active region includes a first portion and a second portion,
the first portion is present on the first main surface side in the first trench,
the second portion is present outside the first trench on the first main surface side, and
the second portion has a width larger than that of the first portion in cross-sectional surface perpendicular to an extending direction of the first trench.

10. The solid-state imaging device according to claim 7, wherein a position of the active region at the first main surface side in a height direction is flush with a position of the semiconductor substrate at the first main surface side in the height direction.

11. The solid-state imaging device according to claim 10, wherein the active region forming the part of the element isolation film has a width larger than that of another part of the element isolation film in cross-sectional surface perpendicular to an extending direction of the first trench.

12. The solid-state imaging device according to claim 1, wherein the element isolation film has a thickness of 2.5 μm or more below the active region.

13. The solid-state imaging device according to claim 1, wherein the transfer transistor includes a gate insulating film and a gate electrode, which are arranged in a second trench formed in the semiconductor substrate from the first main surface toward the second main surface.

14. The solid-state imaging device according to claim 1, wherein the element isolation film is made of a material having a refractive index different from that of the semiconductor substrate.

15. The solid-state imaging device according to claim 1, wherein the element isolation film has a structure including a plurality of layers, and
its outermost layer set in contact with the semiconductor substrate is made of a material having a refractive index different from that of the semiconductor substrate.

16. A solid-state imaging device comprising:
an element isolation film embedded in a first trench penetrating a semiconductor substrate from a first main surface to a second main surface;
a photoelectric conversion element embedded in a pixel region isolated by the element isolation film, the photoelectric conversion element including a P-type region formed on the second main surface side along the first trench and an N-type region formed at a region surrounded by the P-type region; and
a transfer transistor formed at the first main surface and configured to transfer a charge of the photoelectric conversion element,
wherein a part of the element isolation film on the first main surface side or an entirety of the element isolation film is formed of a metal film.

17. The solid-state imaging device according to claim 16, wherein the metal film is connected to a substrate contact that sets the semiconductor substrate at a ground potential.

18. A solid-state imaging device comprising a plurality of pixels arrayed adjacent to each other on a semiconductor substrate and isolated from each other by an element isolation film embedded in a first trench penetrating the semiconductor substrate from a first main surface to a second main surface, wherein
each of the pixels includes
a photoelectric conversion element embedded in a pixel region isolated by the element isolation film, the photoelectric conversion element including a P-type region formed on the second main surface side along the first trench and an N-type region formed at a region surrounded by the P-type region, and
a transfer transistor formed at the first main surface and configured to transfer a charge of the photoelectric conversion element, and
a substrate contact electrode is provided for two pixels, adjacent to each other, of the pixels, such that the substrate contact electrode straddles a part of the element isolation film present between the two pixels.

19. The solid-state imaging device according to claim 18, wherein the substrate contact electrode is formed of a semiconductor film doped with a P-type or an N-type impurity, or a metal film.

20. The solid-state imaging device according to claim 18, wherein the substrate contact electrode is connected to a substrate contact that sets the semiconductor substrate at a ground potential.
